(19) United States
(12) Patent Application Publication
(10) Pub. No.: US 2026/0333955 A1
(43) Pub. Date: Oct. 22, 2026

(54) SEMICONDUCTOR DEVICE

(71) Applicant: Unikorn Semiconductor Corporation, Hsinchu (TW)

(72) Inventors: Pin-Chieh Lin, Hsinchu (TW); Shih-I Chen, Hsinchu (TW); Ching-En Huang, Hsinchu (TW); Chih-Ming Shen, Hsinchu (TW); Jia-De Lian, Hsinchu (TW); Hao-Ming Ku, Hsinchu (TW)

(21) Appl. No.: 19/649,485

(22) Filed: Apr. 16, 2026

(30) Foreign Application Priority Data
Apr. 16, 2025 (TW) 114114368

(51) Int. Cl. H10H 20/841; H10H 20/852

(52) U.S. Cl. CPC H10H 20/841; H10H 20/852

(57) ABSTRACT

A semiconductor device is provided. The semiconductor device includes a first supporting layer having a first material, an epitaxial stack, a first electrode, a protecting structure, and a connecting layer. The epitaxial stack is located on the first supporting layer. The first electrode is located between the first supporting layer and the epitaxial stack. The protecting structure covers the epitaxial stack. The connecting layer is connected to the protecting structure. The first supporting layer includes a protrusion connected to the connecting layer, and the connecting layer includes a second material different from the first material.

### TECHNICAL FIELD

The present disclosure relates to a semiconductor device, and particularly relates to a semiconductor device having a supporting layer.

### CROSS REFERENCE TO RELATED APPLICATION

This application claims the right of priority based on TW Application Serial No. 114114368, filed on Apr. 16, 2025, and the content of which is hereby incorporated by reference in its entirety.

### DESCRIPTION OF BACKGROUND ART

As dimensions of semiconductor devices continue to be scaled down, number of semiconductor devices within a package structure has increased significantly, thereby posing a challenge for manufacturing. Mass transfer process is a method for transferring the semiconductor devices from a carrier to a circuit board or a substrate. However, although existing semiconductor devices have gradually met their intended purposes, they do not satisfy requirements in all respects. Therefore, there are some issues need to be overcome with respect to the semiconductor devices and their forming methods.

### SUMMARY OF THE DISCLOSURE

In some embodiments, a semiconductor device is provided. The semiconductor device includes a first supporting layer, an epitaxial stack, a first electrode, a protecting structure, and a connecting layer. The first supporting layer includes a first material. The epitaxial stack is located on the first supporting layer. The first electrode is located between the first supporting layer and the epitaxial stack. The protecting structure covers the epitaxial stack. The connecting layer is located on the protecting structure and electrically insulated from the first electrode. The first supporting layer has a protrusion connected to the connecting layer, and the connecting layer has a second material different from the first material.

In other embodiments, a semiconductor device is provided. The semiconductor device includes a first supporting layer, an epitaxial stack, a first electrode, and a protecting structure. The epitaxial stack is located on the first supporting layer. The first electrode is located between the first supporting layer and the epitaxial stack. The protecting structure covers the epitaxial stack. The first supporting layer directly contacts the first electrode.

### BRIEF DESCRIPTION OF THE DRAWINGS

Foregoing and other aspects of the embodiments of the present disclosure will be better understood from the following detailed description when read in conjunction with the accompanying drawings. Some features may not be drawn to scale. In fact, the dimensions of various features may be enlarged or reduced for clarity of illustration.

FIG. 1 shows a schematic cross-sectional view of a semiconductor device according to some embodiments of the present disclosure.

FIGS. 2-6 show schematic cross-sectional views of a semiconductor device at different stages of a manufacturing method according to some embodiments of the present disclosure.

FIGS. 7A-7D respectively show a schematic cross-sectional view, a schematic perspective view, a schematic top view, and other schematic top view of the semiconductor device shown in FIG. 4 according to some embodiments of the present disclosure.

FIGS. 8A-8F show different schematic diagrams of a semiconductor device according to other embodiments of the present disclosure.

FIG. 9 shows a schematic cross-sectional view of a semiconductor device according to other embodiments of the present disclosure.

FIGS. 10-12 show schematic cross-sectional views of a semiconductor device at different stages of a manufacturing method according to other embodiments of the present disclosure.

FIG. 13A and FIG. 13B show schematic cross-sectional views of a semiconductor device according to still other embodiments of the present disclosure.

### DETAILED DESCRIPTION OF PREFERRED EMBODIMENTS

In the present disclosure, directional terms such as “on”, “below”, and “between” are intended to describe relative positions among objects and are not intended to limit absolute positions of the objects. In addition, terms “dispose” and “connect” may include situations that two structures are movable or fixed. Furthermore, terms such as “first” and “second” are used to designate different components or to distinguish different embodiments or scopes and are not intended to limit upper or lower bounds on number of the components, nor to limit manufacturing order or placement order of the components.

Unless otherwise specified, the general formula InGaP may represent Inₓ₀Ga₁₋ₓ₀P, in which 0<x0<1; the general formula AlInP may represent Alₓ₁In₁₋ₓ₁P, in which 0<x1<1; the general formula InGaN may represent Inₓ₂Ga₁₋ₓ₂N, in which 0<x2<1; the general formula AlGaN may represent Alₓ₃Ga₁₋ₓ₃N, in which 0<x3<1; the general formula AlGaInP may represent Alₓ₄Gaₓ₅In₁₋ₓ₄₋ₓ₅P, in which 0<x4<1 and 0<x5<1; the general formula InGaAsP may represent Inₓ₆Ga₁₋ₓ₆Asₓ₇P₁₋ₓ₇, in which 0<x6<1 and 0<x7<1; the general formula AlGaInAs may represent Alₓ₈Gaₓ₉In₁₋ₓ₈₋ₓ₉As, in which 0<x8<1 and 0<x9<1; the general formula InGaNAs may represent Inₓ₁₀Ga₁₋ₓ₁₀Nₓ₁₁As₁₋ₓ₁₁, in which 0<x10<1 and 0<x11<1; the general formula InGaAs may represent Inₓ₁₂Ga₁₋ₓ₁₂As, in which 0<x12<1; the general formula AlGaAs may represent Alₓ₁₃Ga₁₋ₓ₁₃As, in which 0<x13<1; the general formula AlInGaN may represent Alₓ₁₄Inₓ₁₅Ga₁₋ₓ₁₄₋ₓ₁₅N, in which 0<x14<1 and 0<x15<1; and the general formula AlGaAsP may represent Alₓ₁₆Ga₁₋ₓ₁₆Asₓ₁₇P₁₋ₓ₁₇, in which 0<x16<1 and 0<x17<1. The composition of each element can be adjusted for different purposes, such as but not limited to tuning the bandgap. In addition, in response to that the semiconductor device is a light-emitting device, a domain wavelength or a peak wavelength of the light-emitting device can also be adjusted accordingly.

The present disclosure provides a semiconductor device, in which a supporting layer is disposed to provide effects of supporting and being readily removable during a transfer process. In addition, the transfer process can be further improved by adjusting relative relationships between the supporting layer and other components (e.g., positions, materials, and shapes), thereby increasing yield of the semiconductor device and reducing manufacturing cost.

Referring to FIG. 1, FIG. 1 shows a schematic cross-sectional view of a semiconductor device 1A according to some embodiments of the present disclosure. As shown in FIG. 1, the semiconductor device 1A includes an epitaxial stack 12 and a first electrode 13A. In some embodiments, the semiconductor device 1A optionally includes a second electrode 13B, a first base 20, an adhesive layer 19, a first supporting layer 18, a connecting layer 15, a protecting structure 14, a reflective structure 16, and a second supporting layer 11.

In some embodiments, the first base 20 may be a temporary carrier, the adhesive layer can bond the first substrate 20 to the first supporting layer 18, and the first supporting layer 18 can connect the first base 20 and the epitaxial stack 12. Specifically, the first base 20, the adhesive layer 19, and the first supporting layer 18 can support the epitaxial stack 12 and other components located on them. In some embodiments, the first supporting layer 18 optionally has a protrusion 180, and the protrusion 180 and the first supporting layer 18 may include the same material or different materials.

The epitaxial stack 12 is located on the first supporting layer 18. In some embodiments, the semiconductor device 1A may be a light-emitting device, and the epitaxial stack 12 is configured to emit light. In some embodiments, the epitaxial stack 12 has a first surface 12A and a second surface 12B relative to the first surface 12A, and the first surface 12A may be a patterned surface (e.g., periodically roughened surface or a randomly roughened surface). In some embodiments, the epitaxial stack 12 may include a first semiconductor structure 120, an active structure 121, and a second semiconductor structure 122 stacked in sequence. The epitaxial stack 12 is located between the first supporting layer 18 and the second supporting layer 11, and the first semiconductor structure 120 is adjacent to the second supporting layer 11. The second semiconductor structure 122 is adjacent to the first supporting layer 18, and the active structure 121 is located between the first semiconductor structure 120 and the second semiconductor structure 122.

As shown in FIG. 1, in some embodiments, the semiconductor device 1A may optionally have a first conductive layer 130 and a second conductive layer 131. The first conductive layer 130 is located between the first electrode 13A and the first semiconductor structure 120, and the first conductive layer 130 is electrically connected to the first electrode 13A and the first semiconductor structure 120 to reduce a first contact resistance between the first electrode 13A and the first semiconductor structure 120. The second conductive layer 131 is located between the second electrode 13B and the second semiconductor structure 122, and the second conductive layer 131 is electrically connected to the second electrode 13B and the second semiconductor structure 122 to reduce a second contact resistance between the second electrode 13B and the second semiconductor structure 122. In other embodiments, the semiconductor device 1A may further include a heightening layer (not shown) located between the first conductive layer 130 and the first electrode 13A, or between the first semiconductor structure 120 and the first electrode 13A. In some embodiments, the heightening layer is provided for making a first electrode surface 13AT of the first electrode 13A and a second electrode surface 13BT of the second electrode 13B be substantially coplanar, thereby facilitating subsequent mounting of the semiconductor device 1A to a circuit carrier.

As shown in FIG. 1, in some embodiments, the protecting structure 14 is located below the epitaxial stack 12 to protect the epitaxial stack 12, thereby preventing the epitaxial stack 12 from being electrically connected to other elements unintentionally. In some embodiments, the protecting structure 14 may optionally include a single-layer structure or a multi-layer structure. In some embodiments, the protecting structure 14 may include a first insulating layer 140 (also referred to as a first protecting layer), a second insulating layer 141 (also referred to as a second protecting layer), and an anti-etching layer 142, and the second insulating layer 141 is located between the first insulating layer 140 and the anti-etching layer 142. In some embodiments, the anti-etching layer 142 may prevent the epitaxial stack 12 from being damaged by a subsequent etching process.

In some embodiments, the reflective structure 16 is located between the first insulating layer 140 and the second insulating layer 141 so that the light emitting by the epitaxial stack 12 exits the semiconductor device 1A in a direction away from the protecting structure 14. In some embodiments, the reflective structure 16 is disposed and embedded between the first insulating layer 140 and the second insulating layer 141, and the reflective structure 16 does not contact the epitaxial stack 12, the first electrode 13A, the second electrode 13B, the first conductive layer 130, and the second conductive layer 131 to prevent from unintended electrical connections.

The first electrode 13A and the second electrode 13B are respectively located between the first supporting layer 18 and the epitaxial stack 12. In some embodiments, the first electrode 13A has a first electrode surface 13AT remote from the second supporting layer 11, the second electrode 13B has a second electrode surface 13BT remote from the second supporting layer 11, and the second electrode surface 13BT is substantially coplanar with the first electrode surface 13AT.

As shown in FIG. 1, the connecting layer 15 is connected to the protecting structure 14 and is located between the first electrode 13A and the second electrode 13B in a horizontal direction. The connecting layer 15 is electrically insulated from the first electrode 13A and the second electrode 13B. In other words, the connecting layer 15 is not electrically connected to the epitaxial stack 12, the first electrode 13A, the second electrode 13B, the first conductive layer 130, and the second conductive layer 131. The connecting layer 15 connects the protrusion 180 of the first supporting layer 18. The connecting layer 15 has a top surface 15T remote from the second supporting layer 11, and the top surface 15T is closer to the second surface 12B of the epitaxial stack 12 than the second electrode surface 13BT. Specifically, a first distance L1 is defined between the top surface 15T and the second surface 12B, a second distance L2 is defined between the second electrode surface 13BT and the second surface 12B, and the second distance L2 is greater than the first distance L1. In some embodiments, a third distance L3 is defined between the first electrode surface 13AT and the second surface 12B, and the third distance L3 is greater than the first distance L1.

In some embodiments, physical properties and/or materials of the first supporting layer 18 are different from those of the connecting layer 15 to reduce a bonding strength between the first supporting layer 18 and the connecting layer, thereby facilitating a subsequent process that separating the first supporting layer (or the protrusion 180) from the connecting layer 15 to transfer the semiconductor device 1A to another base (not shown).

In some embodiments, in a cross-sectional view of the semiconductor device 1A, the connecting layer 15 has a first width d1, and the protrusion 180 has a second width d2 less than the first width d1. In some embodiments, the connecting layer 15 has a first top-view area, and the protrusion 180 has a second top-view area less than the first top-view area. Based on relationships in the widths and the areas, the bonding strength between the connecting layer 15 and the protrusion 180 can be adjusted, thereby improving yield of the subsequent processes (e.g., a transfer process). In some embodiments, the protrusion 180 may contact at any position of the connecting layer 15, such as a center, two sides, a periphery, or corners of the epitaxial stack 12. In some embodiments, the protrusion 180 is disposed between the first electrode 13A and the second electrode 13B. In some embodiments, the protrusion 180 may be disposed at the center, the two sides, the periphery, or the corners of the epitaxial stack 12. The connecting layer 15 may have the same material as the protecting structure 14. In other words, the protrusion 180 contacts the protecting structure 14. In some embodiments, the protecting structure 14 may include the first insulating layer 140, the second insulating layer 141 or the anti-etching layer 142, and the protrusion 180 contacts the anti-etching layer 142. A top-view pattern of the protrusion 180 may be square, circular, or annular.

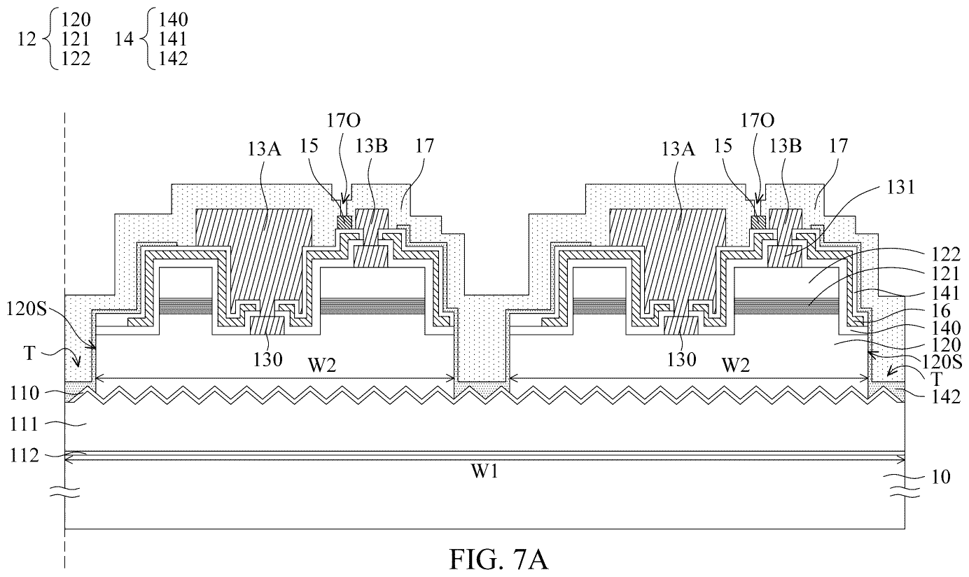

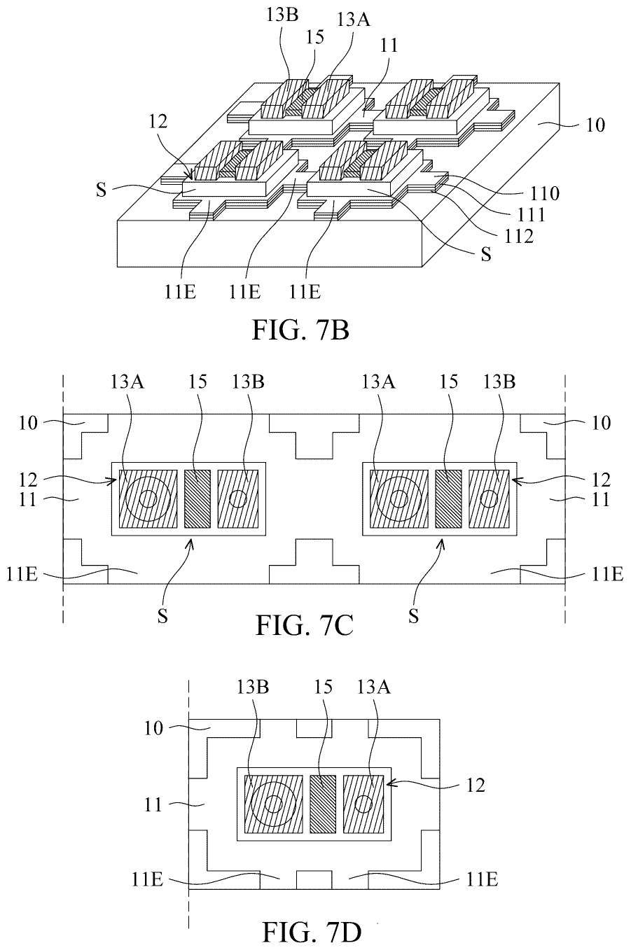

The second supporting layer 11 is located on the epitaxial stack 12, and the epitaxial stack 12 is located between the first electrode 13A, the second electrode 13B, and the second supporting layer 11. In some embodiments, the second supporting layer 11 may serve as a supporting element to make epitaxial stacks 12 of two adjacent semiconductor devices 1A support each other, thereby enhancing lateral support (FIG. 7B can be referred). In some embodiments, the second supporting layer 11 may optionally include a single-layer structure or a multi-layer structure. For example, in some embodiments, the second supporting layer 11 includes a first supporting sub-layer 110, a second supporting sub-layer 111, and a third supporting sub-layer 112.

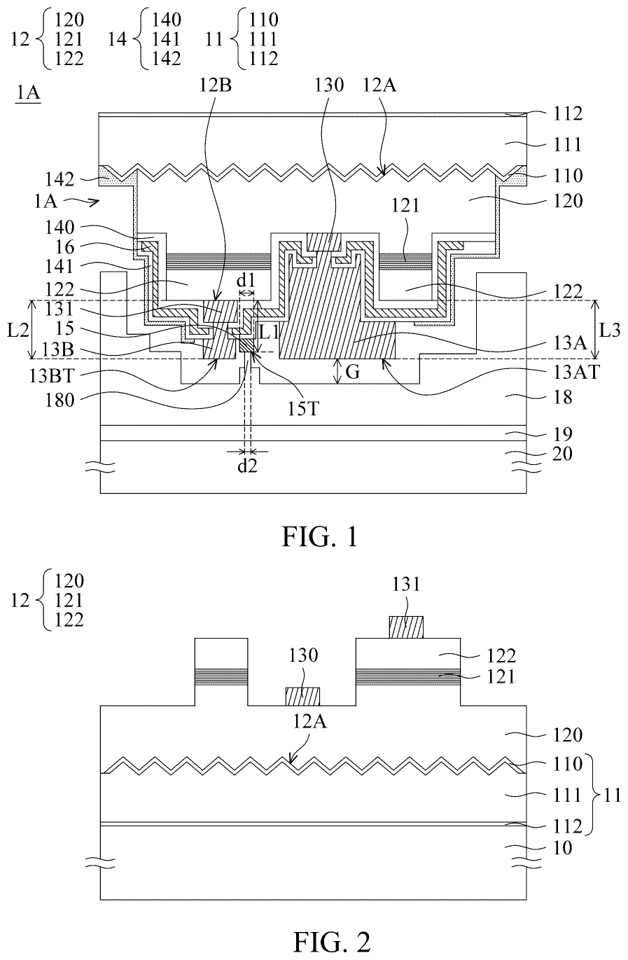

Referring to FIGS. 2-6, FIGS. 2-6 show schematic cross-sectional views of the semiconductor device 1A at different stages of a manufacturing method according to some embodiments of the present disclosure. The manufacturing method described below is merely exemplary, and the present disclosure is not limited to the specific order of the manufacturing method, nor to the specific processes or materials employed therein. In addition, for clarity and ease of understanding, the drawings illustrate only manufacturing processes of a single semiconductor device. However, in practical applications, a plurality of semiconductor devices, whether connected to one another or not, may be formed simultaneously by the method described below. For example, the plurality of semiconductor devices are arranged in an array. First, as shown in FIG. 2, a second base 10 is provided. In some embodiments, the epitaxial stack 12 is grown on another growth substrate (not shown) and is bonded to the second base 10 via the second supporting layer 11. The second base 10 may serve as a carrier. The second supporting layer 11 may serve as an adhesive layer. In some embodiments, the second base 10 may be a growth substrate, and the epitaxial stack 12 is directly grown on the second base 10 without the second supporting layer 11 located between the second base 10 and the epitaxial stack 12.

In some embodiments, the epitaxial stack 12 may be grown by metal-organic chemical vapor deposition (MOCVD), molecular beam epitaxy (MBE), liquid phase epitaxy (LPE), vapor phase epitaxy (VPE), or atomic layer epitaxy (ALE).

Then, the first conductive layer 130 and the second conductive layer 131 are disposed on the epitaxial stack 12. The first conductive layer 130 directly contacts and electrically connects to the first semiconductor structure 120, and the second conductive layer 131 directly contacts and electrically connects to the second semiconductor structure 122. In some embodiments, the first conductive layer 130 or the second conductive layer 131 may be formed by an electroplating process, or an etching process. In some embodiments, the first conductive layer 130 and the second conductive layer 131 may be formed in same processes or different processes.

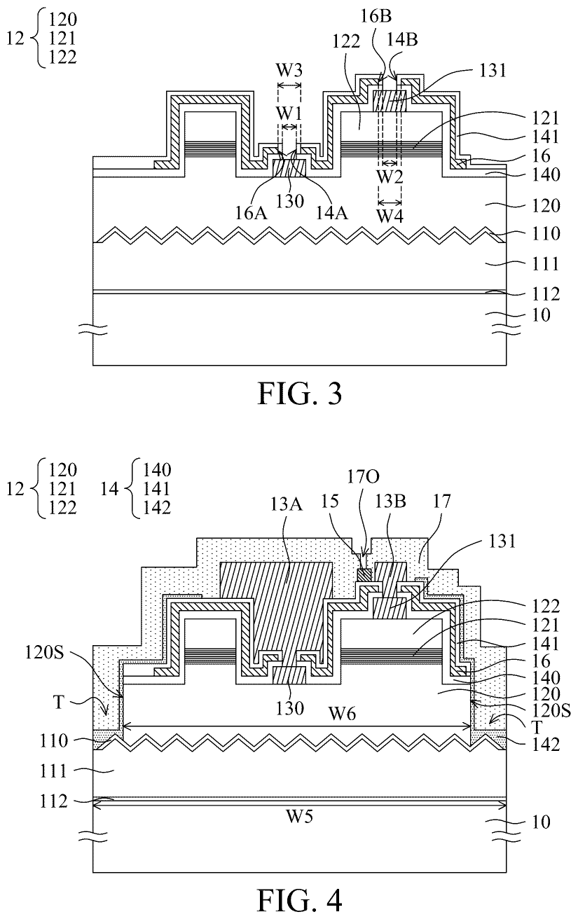

Following FIG. 2, as shown in FIG. 3, the first insulating layer 140, the reflective structure 16, and the second insulating layer 141 are sequentially formed on the epitaxial stack 12. In some embodiments, the first insulating layer 140, the reflective structure 16, and the second insulating layer 141 are disposed or conformally disposed on the epitaxial stack 12. The first insulating layer 140 and the second insulating layer 141 collectively include a first opening 14A located on the first conductive layer 130 and a second opening 14B located on the second conductive layer 131, the first opening 14A has a first aperture W1, and the second opening 14B has a second aperture W2. The reflective structure 16 includes a third opening 16A and a fourth opening 16B, the third opening 16A is located on the first conductive layer 130 aligned with the first opening 14A, and the fourth opening 16B is located on the second conductive layer 131 aligned with the second opening 14B. The third opening 16A has a third aperture W3 greater than the first aperture W1 so that sidewalls of the reflective structure 16 are covered by the first insulating layer 140 and/or the second insulating layer 141. Likewise, the fourth opening 16B has a fourth aperture W4 greater than the second aperture W2.

Following FIG. 3, as shown in FIG. 4, the first electrode 13A is disposed on the first conductive layer 130, and the second electrode 13B is disposed on the second conductive layer 131. Next, the connecting layer 15 is disposed on the second insulating layer 141 and located between the first electrode 13A and the second electrode 13B, and the anti-etching layer 142 is disposed to cover the second insulating layer 141, the first electrode 13A, and the second electrode 13B. Then, an isolation trench T is formed in the epitaxial stack 12 to partition the epitaxial stack 12 into multiple independent semiconductor structures (FIG. 7 may be referred). For example, a plurality of epitaxial structures may be formed by the processes shown in FIG. 2, and the plurality of epitaxial structures is divided into multiple epitaxial stacks 12 by the present process. The multiple epitaxial stacks 12 still share the second base 10 and the second supporting layer 11. In some embodiments, after the isolation trench T is formed, a side surface 120S of the first semiconductor structure 120 is exposed, and a width W5 of the second supporting layer 11 is greater than a width W6 of the epitaxial stack 12. After that, the anti-etching layer 142 is disposed to cover the second insulating layer 141 and the side surface 120S of the first semiconductor structure 120. Finally, a sacrificial layer 17 is disposed to cover the first electrode 13A, the second electrode 13B, the anti-etching layer 142, and the isolation trench T. The sacrificial layer 17 has a fifth opening 17O, and the connecting layer 15 is exposed through the fifth opening 17O.

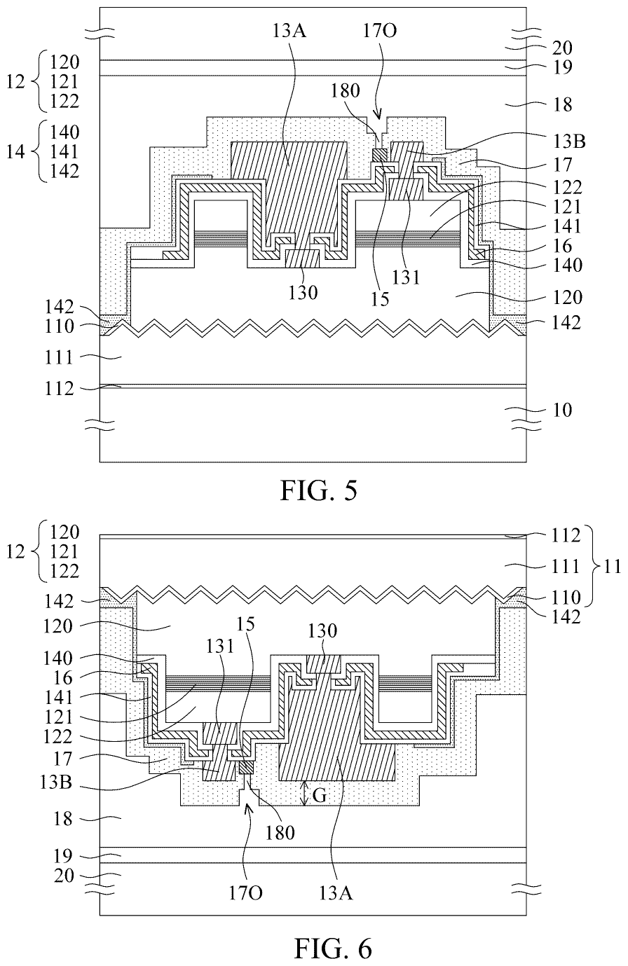

Following FIG. 4, as shown in FIG. 5, a first base 20 is prepared, and the adhesive layer 19 and the first supporting layer 18 are disposed on a surface of the first base 20. Next, a bonding step is performed with the first supporting layer 18 facing toward the sacrificial layer 17 to bond the epitaxial stack 12 to the first base 20. In some embodiments, the bonding step may employ a wafer-wafer bonding process, in which the first base 20 with a large area is bonded to a plurality of semiconductor stacks (i.e., the epitaxial stack 12) located on the second base 20 simultaneously. In some embodiments, the first supporting layer 18 is filled in the fifth opening 17O of the sacrificial layer 17 to form the protrusion 180 and contact the connecting layer 15.

Following FIG. 5, as shown in FIG. 6, the second base 10 may optionally be removed, and then the sacrificial layer 17 is removed to form the semiconductor device 1A shown in FIG. 1. For example, the sacrificial layer 17 may be removed in the etching process according to an etching selectivity while retaining the first supporting layer 18 and the protecting structure 14. The anti-etching layer 142 can protect the epitaxial stack 12 from damage during the etching process. After the sacrificial layer 17 is removed, the epitaxial stack 12 and the first base 20 are interconnected via the connecting layer 15 and the protrusion 180 of the first supporting layer 18, and remaining portions are spaced apart by a gap G with different heights at different locations.

In some embodiments, the second base 10 may include a semiconductor material or an insulating material. For example, the semiconductor material may be silicon (Si), gallium oxide (Ga2O3), gallium nitride (GaN), aluminum gallium nitride (AlGaN), aluminum nitride (AlN), gallium phosphide (GaP), gallium arsenide (GaAs), or aluminum gallium arsenide (AlGaAs). The insulating material may be diamond (C), silicon carbide (SiC), sapphire, or glass.

In some embodiments, the second supporting layer 11 may include an insulating material, such as benzocyclobutene (BCB) resin, epoxy resin, polyimide (PI), polybenzoxazole (PBO), silicone, silicon oxide, silicon nitride (SiₓN_{y}), or aluminum oxide (Al₂O₃).

In some embodiments, the first semiconductor structure 120, the active structure 121, and the second semiconductor structure 122 may include a group II-VI material or a group III-V material. For example, the group II-VI material may include zinc selenide (ZnSe). The group III-V material may include aluminum gallium indium arsenide (AlGaInAs), aluminum gallium indium phosphide (AlGaInP), indium gallium phosphide (InGaP), indium gallium arsenide (InGaAs), aluminum indium phosphide (AlInP), indium gallium arsenide phosphide (InGaAsP), aluminum gallium arsenide (AlGaAs), aluminum gallium arsenide phosphide (AlGaAsP), indium gallium nitride (InGaN), indium gallium nitride arsenide (InGaNAs), aluminum gallium nitride (AlGaN), or aluminum indium gallium nitride (AlInGaN).

In some embodiments, a doping process may be performed on the first semiconductor structure 120 and the second semiconductor structure 122. Accordingly, the first semiconductor structure 120 includes a first dopant and has a first conductivity type, and the second semiconductor structure 122 includes a second dopant and has a second conductivity type different from the first conductivity type. For example, the doping process may include in-situ doping during an epitaxial growth, or ion implantation after the epitaxial growth. In some embodiments, the first conductivity type may be p-type providing holes, and the second conductivity type may be n-type providing electrons. Alternatively, the first conductivity type may be n-type providing the electrons, and the second conductivity type may be p-type providing the holes. In some embodiments, the first dopant or the second dopant may be magnesium (Mg), zinc (Zn), silicon (Si), carbon (C), or tellurium (Te).

In some embodiments, the active structure 121 can emit light, and the light emitted by the active structure 121 may include visible light or invisible light (e.g., infrared or ultraviolet). A wavelength of the light emitted by the active structure 121 depends on material compositions of the active structure 121. Based on the material compositions, the active structure 121 can emit red light with its wavelength between 640 nanometer (nm) and 650 nm, green light with its wavelength between 530 nm and 570 nm, medium-wave ultraviolet (UV-B) and short-wave ultraviolet (UV-C) with their wavelength between 220 nm and 320 nm, near-ultraviolet (UV-A) with its wavelength approximately between 320 nm and 420 nm, or infrared light with its wavelength approximately between 750 nm and 2000 nm. In some embodiments, the epitaxial stack 12 may include a quantum well (QW) or multi-quantum wells (MQW).

In some embodiments, material of the first conductive layer 130 or material of the second conductive layer 131 may include metal, metal oxide, metal nitride, or metal silicide. In some embodiments, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), or an alloy thereof. In some embodiments, the metal nitride may be tantalum nitride (TaN) or titanium nitride (TiN). In some embodiments, the metal silicide may be tungsten silicide (WSi₂). In some embodiments, the metal oxide may be indium tin oxide (ITO), indium oxide (InO), tin oxide (SnO), cadmium tin oxide (CTO), antimony tin oxide (ATO), aluminum-doped zinc oxide (AZO), zinc tin oxide (ZTO), gallium-doped zinc oxide (GZO), indium tungsten oxide (IWO), zinc oxide (ZnO), indium zinc oxide (IZO), or indium gallium zinc oxide (IGZO). In some embodiments, the material of the first conductive layer 130 may be the same as or different from the material of the second conductive layer 131.

In some embodiments, material of the first electrode 13A or material of the second electrode 13B may include metal, metal oxide, metal nitride, or metal silicide. In some embodiments, the material of the first electrode 13A may be similar to or the same as the material of the first conductive layer 130. In some embodiments, the material of the second electrode 13B may be similar to or the same as the material of the second conductive layer 131.

In some embodiments, the first insulating layer 140, the second insulating layer 141, or the anti-etching layer 142 may include dielectric material. The dielectric material may include oxides, nitrides, or polymer materials, such as silicon dioxide (SiO2), silicon nitride (SixNy), aluminum oxide (Al₂O₃), aluminum nitride (AlN), or benzocyclobutene (BCB) resin. In some embodiments, materials of the first insulating layer 140, the second insulating layer 141, and the anti-etching layer 142 may be the same or different.

In some embodiments, the connecting layer 15 may include conductive material or dielectric material. The conductive material may include metal, metal oxide, metal nitride, or metal silicide. The dielectric material may include oxide, nitride, or polymer material, such as silicon dioxide (SiO2) and silicon nitride (SiₓN_{y}). In some embodiments, material of the connection layer 15 may be similar to or the same as any one of the materials of the first conductive layer 130, the second conductive layer 131, the first electrode 13A, the second electrode 13B, or the protecting structure 14.

In some embodiments, the reflective structure 16 may include conductive material or dielectric material to reflect the light emitted by the active structure 121. In some embodiments, the reflective structure 16 may include a single layer or a multilayer stack with specific thicknesses and stack sequence (e.g., a Bragg reflector).

In some embodiments, the sacrificial layer 17 may include dielectric material or organic material. In some embodiments, material of the sacrificial layer 17 is different from the material of the protecting structure 14 to provide a different etching selectivity with respect to the anti-etching layer 142 of the protecting structure 14, thereby allowing the sacrificial layer 17 to be removed faster than the anti-etching layer 142 during subsequent processes.

In some embodiments, the first supporting layer 18 may include dielectric material. In some embodiments, material of the first supporting layer 18 may be different from the material of the sacrificial layer 17 to provide a different etching selectivity with respect to the sacrificial layer 17, thereby allowing the first supporting layer 18 to be remained during subsequent processes. The dielectric material may include oxide, nitride, or polymer material, such as silicon dioxide (SiO₂), silicon nitride (SiₓN_{y}), aluminum oxide (Al₂O₃), aluminum nitride (AlN), or benzocyclobutene (BCB) resin.

In some embodiments, the adhesive layer 19 may include epoxy resin, polyimide (PI), polybenzoxazole (PBO), silicone, silicon oxide, or silicon nitride (SiₓN_{y}).

In some embodiments, the first base 20 may include silicon (Si), glass, sapphire, or polymer material (e.g., silicone, polyethylene terephthalate (PET), or polyimide (PI)).

Referring to FIGS. 7A-7D, FIGS. 7A-7D respectively show a schematic cross-sectional view, a schematic perspective view, a schematic top view, and other schematic top view of the semiconductor device 1A shown in FIG. 4 according to some embodiments of the present disclosure. As shown in FIG. 7A and FIG. 7B, after the isolation trench T is formed, a patterning process may be performed on the second supporting layer 11. In some embodiments, the second supporting layer 11 is configured to temporarily connect two epitaxial stacks 12 adjacent to each other, and the second supporting layer 11 between the two epitaxial stacks 12 is removed to separate the two epitaxial stacks 12 from each other during a subsequent transfer process. In other embodiments, the isolation trench T and the second supporting layer 11 may be patterned in the same process.

In some embodiments, shape of the second supporting layer 11 after patterning, as shown in FIG. 7B, is provided by way of example only. In other embodiments, the second supporting layer 11 may have a different shape or connect the two epitaxial stacks 12 in a different manner. As shown in FIG. 7B, in a top view, the epitaxial stack 12 has a plurality of side edges S. The second supporting layer 11 may protrude along one of the plurality of side edges S of the epitaxial stack 12 to connect to an adjacent epitaxial stack 12, and each of the plurality of side edges S has an extension portion 11E. As shown in FIG. 7C, a width of the extension portion 11E. may be equal to or greater than a width of the epitaxial stack 12. As shown in FIG. 7D, the second supporting layer 11 may include multiple extension portions 11E (e.g., two) on any of the plurality of side edges S of the epitaxial stack 12. Shape and size of the second supporting layer 11, and number of the multiple extension portions 11E, may be designed according to practical requirements and applications to improve the yield of subsequent transfer processes.

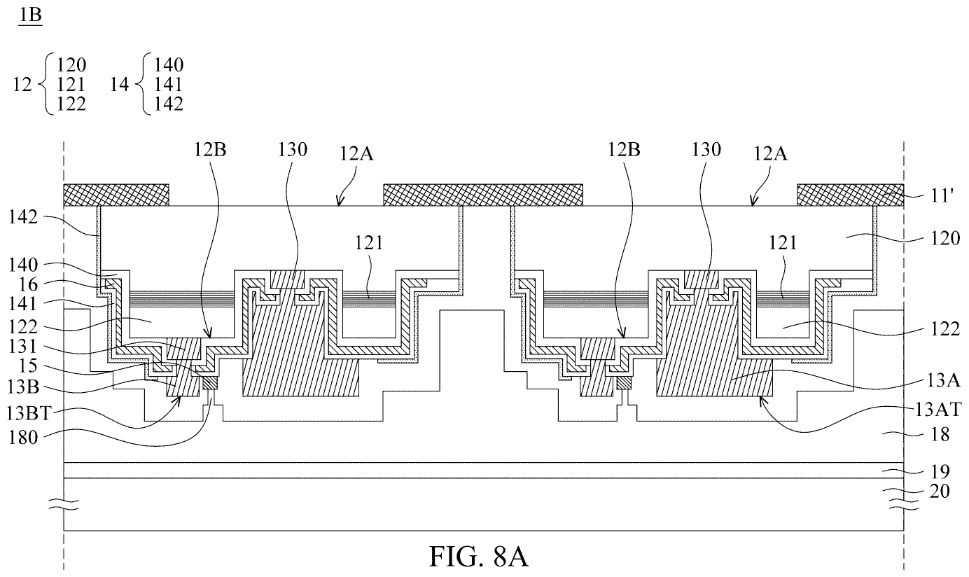

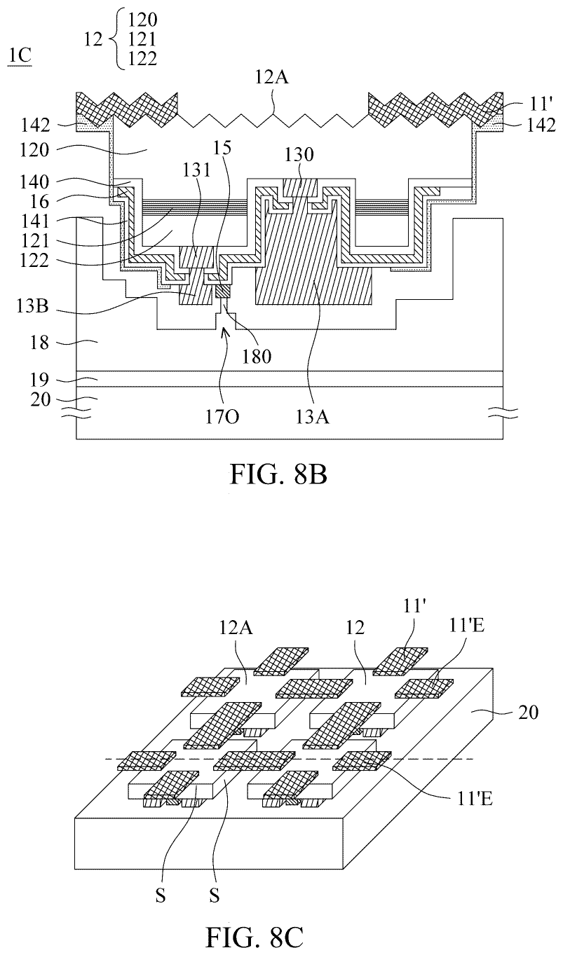

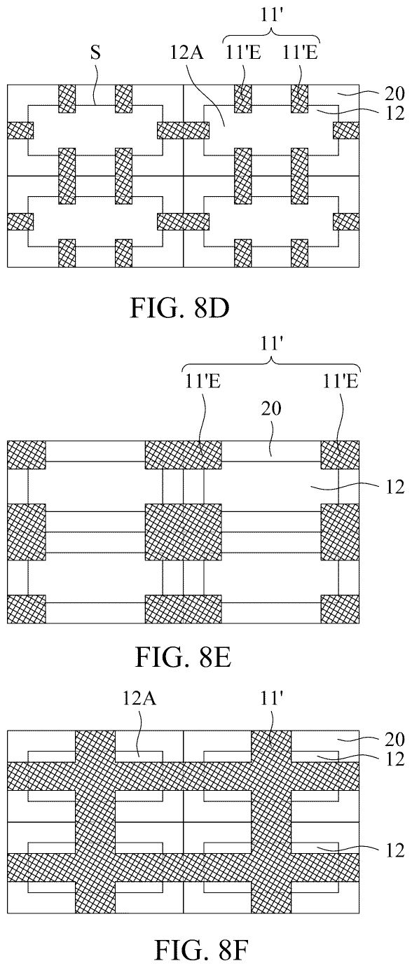

Referring to FIGS. 8A-8F, FIGS. 8A-8F show different schematic diagrams of a semiconductor device according to other embodiments of the present disclosure. FIG. 8A shows a schematic cross-sectional view of the semiconductor device 1B. FIG. 8B shows a schematic cross-sectional view of the semiconductor device 1C. FIG. 8C shows a schematic perspective view of the semiconductor device 1B. FIG. 8D-8F show schematic top view of other semiconductor devices.

As shown in FIG. 8A, components of the semiconductor device 1B and their interconnections are similar to those of the semiconductor device 1A shown in FIG. 1A, except that a portion of the first surface 12A of the semiconductor device 1B is not covered by a second supporting layer 11′. Specifically, detailed process for the semiconductor device 1B may optionally remove the first supporting sub-layer 110, the second supporting sub-layer 111, and the third supporting sub-layer 112 concurrently or subsequently after removing the second base 10 as shown in FIG. 6. Then, the second supporting layer 11′ is formed on the first surface 12A of the epitaxial stack 12. The second supporting layer 11′ is configured to connect two adjacent epitaxial stacks 12 and does not serve as an adhesive layer during processes of the epitaxial stack 12. In some embodiments, the first surface 12A may be a planar surface or a textured surface with patterned structures.

As shown in FIG. 8C, the second supporting layer 11′ has a plurality of extension portions 11′E spaced apart from each other. The plurality of extension portions 11′E may be disposed on four side edges S of the epitaxial stack 12, and two adjacent epitaxial stacks 12 are connected to each other via the same extension portion 11′E. In some embodiments, each of the plurality of extension portions includes a first portion and a second portion, the first portion is disposed on the first surface 12A of the epitaxial stack 12, and the second portion is extending from the first portion beyond the side surface 120S of the epitaxial stack 12. The second supporting layer 11′ may include epoxy resin, polyimide (PI), polybenzoxazole (PBO), silicone, silicon oxide, silicon nitride (SiₓN_{y}), aluminum oxide (Al2O3), or benzocyclobutene (BCB) resin. In some embodiments, materials of the plurality of extension portions 11′E of the second supporting layer 11′ may be different from or the same as the material of the second supporting layer 11.

In other embodiments, the epitaxial stack 12 of the semiconductor device 1C shown in FIG. 8B is directly grown on the second base 10 without forming the first supporting sub-layer 110, the second supporting sub-layer 111, and the third supporting sub-layer 112 to connect to the second base 10. Accordingly, the second base 10 can be directly removed by a substrate removal process (e.g., a laser lift-off process), and the second supporting layer 11′ is subsequently formed on the first surface 12A of the epitaxial stack 12. In some embodiments, since surface of the second base 10 has a patterned structure to improve epitaxial quality, the first surface 12A accordingly has a patterned structure. In some embodiments, the second supporting layer 11′ may be conformally formed to cover part or all the first surface 12A optionally, and the second supporting layer 11′ accordingly has a patterned structure. In some embodiments, the first portion of each of the plurality of extension portions 11′E of the second supporting layer 11′ optionally includes a patterned surface, and the second portion also optionally includes a patterned surface.

As shown in FIGS. 8D-8F, the second supporting layer 11′ may be disposed on the first surface 12A of the epitaxial stack 12 in different ways. As shown in FIG. 8D, any side edge S of the epitaxial stack 12 may have two or more extension portions 11′E of the second supporting layer 11′. As shown in FIG. 8E, the plurality of extension portions 11′E of the second supporting layer 11′ may be disposed at corners of the epitaxial stack 12 to connect to another epitaxial stack 12. In some embodiments, adjacent four epitaxial stacks 12 are connected to each other via the same extension portion 11′E. As shown in FIG. 8F, the second supporting layer 11′ may be a continuous structure and continuously cover first surfaces 12A of a plurality of epitaxial stacks 12 to connect the plurality of epitaxial stacks 12.

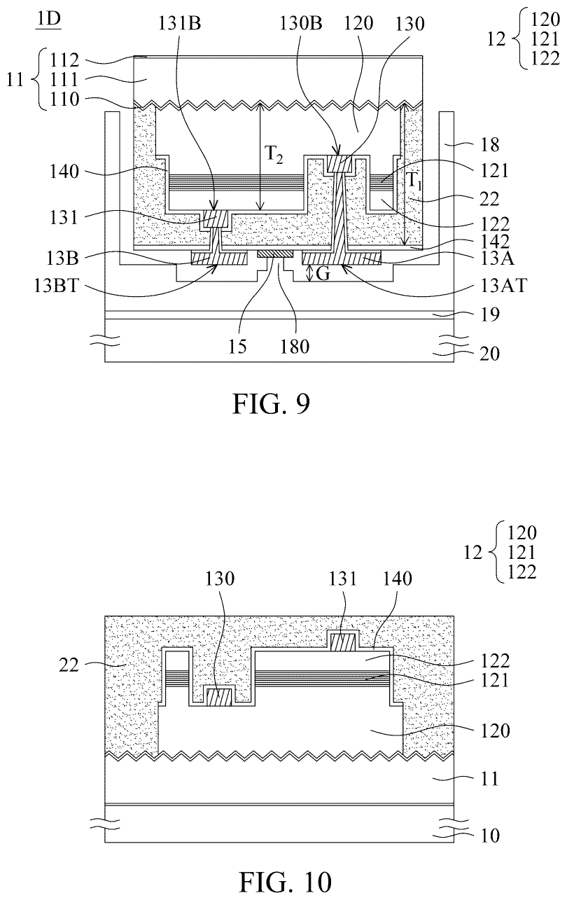

FIG. 9 shows a schematic cross-sectional view of a semiconductor device 1D according to other embodiments of the present disclosure. As shown in FIG. 9, components of the semiconductor device 1D and their interconnections are similar to those of the semiconductor device 1A shown in FIG. 1A, except that the semiconductor device 1D does not include the second insulating layer 141 and the reflective structure 16 and further includes a planarization layer 22 covering the epitaxial stack 12 and the first insulating layer 140. The semiconductor device 1D may optionally have an anti-etching layer 142 located between the planarization layer 22 and the first electrode 13A, as well as between the planarization layer 22 and the second electrode 13B. The planarization layer has a first thickness T₁, and the epitaxial stack 12 has a second thickness T₂ less than the first thickness T₁.

In some embodiments, the planarization layer 22 is configured to heighten the first electrode 13A and the second electrode 13B to make the first electrode surface 13AT and the second electrode surface 13BT be substantially coplanar, thereby facilitating subsequent mounting of the semiconductor device 1D to a circuit carrier.

FIGS. 10-12 show schematic cross-sectional views of a semiconductor device 1D at different stages of a manufacturing method according to other embodiments of the present disclosure. First, as shown in FIG. 10, a second base 10, a second supporting layer 11, an epitaxial stack 12, a first conductive layer 130, a second conductive layer 131, and a first insulating layer 140 are provided. These components may be similar or identical to those described in the foregoing embodiments, and thus further description is omitted. Then, a planarization layer 22 is disposed on the first insulating layer 140.

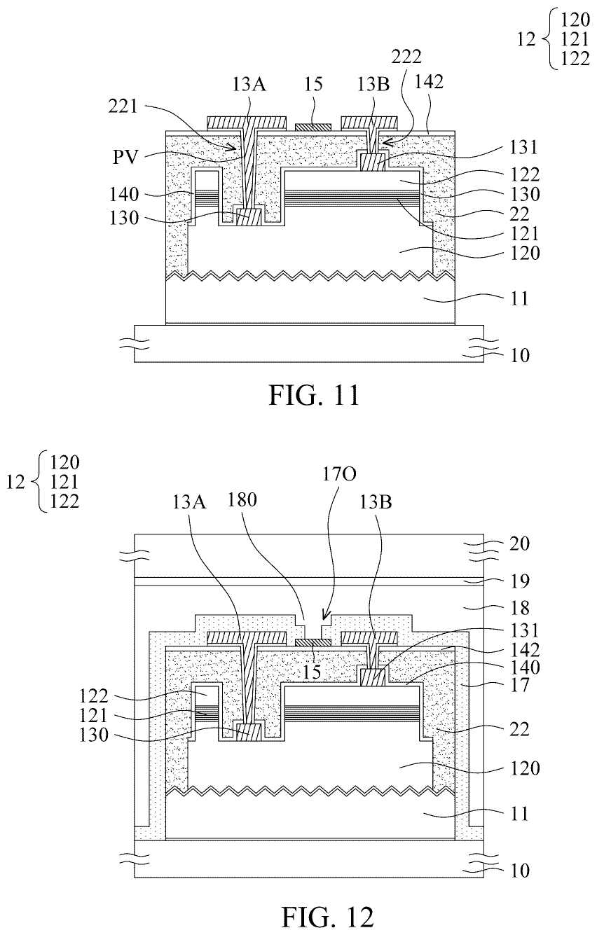

Following FIG. 10, as shown in FIG. 11, an anti-etching layer 142 is disposed on the planarization layer 22. Next, a first opening 221 and a second opening 222 are disposed in the planarization layer 22, and an insulating structure PV is deposited on sidewalls of the first opening 221 and the second opening 222 to expose the first conductive layer 130 and the second conductive layer 131. Then, a first electrode 13A is filled into the first opening 221 to contact with the first conductive layer 130, and a second electrode 13B is filled into the second opening 222 to contact with the second conductive layer 131. The first electrode 13A is electrically connected to the first semiconductor structure 120 via the first conductive layer 130, and the second electrode 13B is electrically connected to the second semiconductor structure 122 via the second conductive layer 131. After that, a connecting layer 15 is disposed on the planarization layer 22 or the anti-etching layer 142.

Following FIG. 11, as shown in FIG. 12, a sacrificial layer 17 is disposed on the planarization layer 22. The sacrificial layer 17 has a fifth opening 17O, and the connecting layer 15 is exposed through the fifth opening 17O. Next, a first base 20 is prepared, and an adhesive layer 19 and a first supporting layer 18 are disposed on a surface of the first base 20. Next, a bonding step is performed with the first supporting layer 18 facing toward the sacrificial layer 17 to bond the epitaxial stack 12 to the first base 20. In some embodiments, the bonding step may employ a wafer-wafer bonding process, in which the first base 20 with a large area is bonded to a plurality of semiconductor stacks (i.e., the epitaxial stack 12) located on the second base 20 simultaneously. Then, the sacrificial layer 17 is removed to obtain the semiconductor device 1D shown in FIG. 9. For example, the sacrificial layer 17 is removed in the etching process according to an etching selectivity. The epitaxial stack 12 and the first base 20 are interconnected via the connecting layer 15 and a protrusion 180 of the first supporting layer 18, and remaining portions are spaced apart by a gap G.

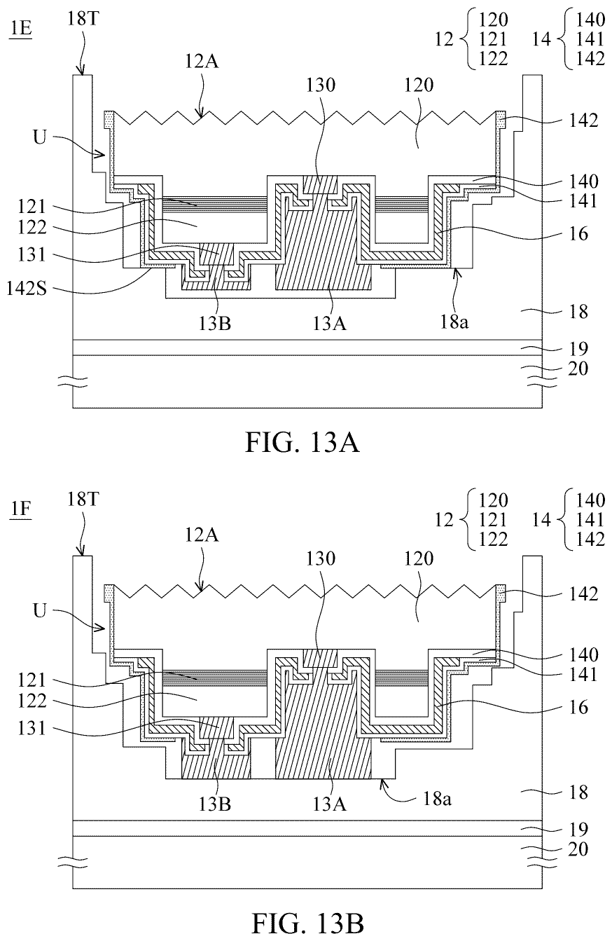

FIG. 13A shows a schematic cross-sectional view of a semiconductor device 1E according to still other embodiments of the present disclosure. As shown in FIG. 13A, components of the semiconductor device 1E and their interconnections are similar to those of the semiconductor device 1A shown in FIG. 1A, except that the semiconductor device 1E does not have the connecting layer 15 and the first supporting layer 18 contacts the protecting structure 14. Specifically, the anti-etching layer 142 has a third surface 142S, and the first supporting layer 18 directly contacts part or all of the third surface 142S. The first supporting layer 18 has a fourth surface 18T away from the first base 20, and a surface (e.g., the first surface 12A) of the epitaxial stack 12 away from the first base 20 is not coplanar with the fourth surface 18T of the first supporting layer 18. The fourth surface 18T is farther from the first base 20 than the first surface 12A.

FIG. 13B shows a schematic cross-sectional view of a semiconductor device 1F according to still other embodiments of the present disclosure. As shown in FIG. 13B, components of the semiconductor device 1F and their interconnections are similar to those of the semiconductor device 1E shown in FIG. 13A, except that in the semiconductor device 1F, the first electrode 13A and the second electrode 13B directly contact the first supporting layer. Similarly, the first surface 12A of the epitaxial stack 12 away from the first base 20 is not coplanar with the fourth surface 18T of the first supporting layer 18, and the fourth surface 18T is farther from the first base 20 than the first surface 12A.

In conclusion, according to any of the embodiments, the semiconductor device employs the supporting layer to support the epitaxial stack, thereby providing robust support on the first base and facilitating effective lift-off when the epitaxial stack is transferred to another base (i.e., the transfer process). In addition, by adjusting relative relationships between the support layer and other elements (e.g., position, material, and shape), the transfer process can be further improved, thereby increasing yield of the semiconductor device and reducing manufacturing cost.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

What is claimed is:

1. A semiconductor device, comprising:
a first supporting layer comprising a first material;
an epitaxial stack located on the first supporting layer;
a first electrode located between the first supporting layer and the epitaxial stack;
a protecting structure covering the epitaxial stack; and
a connecting layer connected to the protecting structure;
wherein the first supporting layer comprises a protrusion connected to the connecting layer, and the connecting layer comprises a second material different from the first material.

2. The semiconductor device according to claim 1, further comprising:
a second supporting layer covering the epitaxial stack;
wherein, the epitaxial stack is located between the first electrode and the second supporting layer.

3. The semiconductor device according to claim 2, wherein in a cross-sectional view, a first width of the second supporting layer is greater than a second width of the epitaxial stack.

4. The semiconductor device according to claim 1, further comprising:
a planarization layer covering the epitaxial stack;
wherein a first maximum thickness of the planarization layer is greater than a second maximum thickness of the epitaxial stack.

5. The semiconductor device according to claim 1, further comprising:
a second electrode located between the first supporting layer and the epitaxial stack;
wherein the connecting layer is located between the second electrode and the first electrode.

6. The semiconductor device according to claim 5, wherein the first electrode comprises a first surface adjacent to the epitaxial stack and a second surface remote from the epitaxial stack, the second electrode comprises a third surface adjacent to the epitaxial stack and a fourth surface remote from the epitaxial stack; and
the first surface is not coplanar with the third surface, and the second surface is coplanar with the fourth surface.

7. The semiconductor device according to claim 5, wherein the first electrode comprises a first surface, the second electrode comprises a second surface, the connecting layer has a fifth surface, and the first surface and the second surface are not coplanar with the fifth surface.

8. The semiconductor device according to claim 1, wherein the connecting layer comprises a first top-view area, and the protrusion comprises a second top-view area less than the first top-view area.

9. The semiconductor device according to claim 1, wherein the protecting structure comprises a first insulating layer, a second insulating layer, and an anti-etching layer, and the second insulating layer is located between the first insulating layer and the anti-etching layer.

10. The semiconductor device according to claim 9, further comprising:
a reflective structure located between the first insulating layer and the second insulating layer.

11. The semiconductor device according to claim 1, further comprising:
a base; and
an adhesive layer located between the first supporting layer and the base;
wherein the first supporting layer connects the base and the epitaxial stack.

12. The semiconductor device according to claim 1, wherein the connecting layer is electrically insulated from the first electrode.

13. The semiconductor device according to claim 1, wherein the epitaxial stack has a patterned surface.

14. A semiconductor device, comprising:
a first supporting layer;
an epitaxial stack located on the first supporting layer, and comprising a first surface, a second surface opposite to the first surface, and a side surface;
a first electrode located between the first supporting layer and the epitaxial stack; and
a second supporting layer comprising a first portion disposed on the first surface and a second portion extending from the first portion beyond the side surface;
wherein the second portion of the second supporting layer comprises a first patterned surface.

15. The semiconductor device according to claim 14, wherein the first surface of the epitaxial stack comprises a second patterned surface.

16. The semiconductor device according to claim 14, further comprising a reflective structure covering the second surface without covering the side surface.

17. The semiconductor device according to claim 16, wherein the reflective structure is devoid of covering the first surface.

18. The semiconductor device according to claim 16, wherein the reflective structure comprises a Bragg reflector.

19. The semiconductor device according to claim 14, further comprising a second electrode located between the first supporting layer and the epitaxial stack.

20. The semiconductor device according to claim 14, wherein the first electrode is devoid of directly contacting the first supporting layer.
